(19) United States
(12) Patent Application Publication
(10) Pub. No.: US 2018/0211707 A1
(43) Pub. Date: Jul. 26, 2018

(54) SEMICONDUCTOR MEMORY DEVICE AND METHOD OF CONTROLLING SEMICONDUCTOR MEMORY DEVICE

(71) Applicant: Toshiba Memory Corporation, Tokyo (JP)

(72) Inventor: Yusuke NOSAKA, Inagi Tokyo (JP)

(21) Appl. No.: 15/694,975

(22) Filed: Sep. 4, 2017

(30) Foreign Application Priority Data
Jan. 23, 2017 (JP) 2017-009680

(51) Int. Cl. G11C 16/08; G11C 16/04; G06F 12/02; G06F 3/06; G11C 16/26; G11C 16/10

(52) U.S. Cl. CPC G11C 16/08; G11C 16/0483; G11C 16/10; G06F 3/0679; G11C 16/26; G06F 12/0246

(57) ABSTRACT

A semiconductor memory device includes a nonvolatile semiconductor memory including a plurality of memory cells and a plurality of word lines each connected to a page unit of memory cells, and a memory controller that controls reading of data from the memory cells. The nonvolatile semiconductor memory performs either a first read operation in which all data from the page unit of memory cells connected to a selected word line among the plurality of word lines is read, or a second read operation in which a portion of the data from the page unit of memory cells connected to a selected word line among the plurality of word lines is read, and the memory controller is configured to cause the nonvolatile semiconductor memory to perform the second read operation when data at a target physical address of a read request can be read in a single second read operation.

### CROSS-REFERENCE TO RELATED APPLICATION

This application is based upon and claims the benefit of priority from Japanese Patent Application No. 2017-009680, filed Jan. 23, 2017, the entire contents of which are incorporated herein by reference.

### FIELD

Embodiments described herein relate generally to semiconductor memory devices and methods of controlling the semiconductor memory devices.

### BACKGROUND

In a semiconductor memory device including a nonvolatile semiconductor memory, as miniaturization of semiconductor devices advances, reduction in reading performance due to increases in reading times of the data from memory cells becomes more significant.

### DESCRIPTION OF THE DRAWINGS

FIG. 1 is a block diagram of a semiconductor memory device according to a first embodiment.

FIG. 2 schematically illustrates various functional units generated by executing firmware according to the first embodiment.

FIGS. 3-5 schematically illustrate a configuration of a NAND flash memory according to the first embodiment.

FIGS. 6A to 6D schematically illustrate structures of a cluster according to the first embodiment.

FIGS. 7A to 7C schematically illustrate relationships between a cluster according to the first embodiment and a physical page.

FIG. 8 schematically illustrates a logical page according to the first embodiment.

FIG. 9 schematically illustrates a logical block according to the first embodiment.

FIGS. 10A and 10B schematically illustrate a first read operation according to the first embodiment.

FIGS. 11A and 11B schematically illustrate a second read operation according to the first embodiment.

FIG. 12 is a timing chart that illustrates switching between the first read operation and the second read operation according to the first embodiment.

FIGS. 13A and 13B schematically illustrate an example of a read operation according to the first embodiment.

FIGS. 14A and 14B schematically illustrate another example of the read operation according to the first embodiment.

FIG. 15 is a block diagram that illustrates a configuration of a memory access controller according to the first embodiment.

FIG. 16 is a flow diagram that illustrates a sequence of generation of a read request according to the first embodiment.

FIG. 17 schematically illustrates an example of a read operation according to a second embodiment.

FIGS. 18A and 18B schematically illustrate a third read operation according to the second embodiment.

FIG. 19 schematically illustrates another example of a read operation according to the second embodiment.

FIG. 20 is a block diagram that illustrates a configuration of a memory access controller according to the second embodiment.

FIG. 21 is a flow diagram that illustrates a sequence of generation of a read request according to the second embodiment.

### DETAILED DESCRIPTION

In general, according to an embodiment, there is provided a semiconductor memory device including a nonvolatile semiconductor memory including a plurality of memory cells in an array, a plurality of word lines each connected to a page unit of memory cells, and a buffer for temporarily storing data read from the plurality of memory cells. The semiconductor memory device further includes a memory controller connected to the nonvolatile semiconductor memory and configured to control reading of data from the plurality of memory cells. The nonvolatile semiconductor memory is configured to perform a first read operation in which all data from the page unit of memory cells connected to a selected word line among the plurality of word lines is read and then stored in the buffer, and a second read operation in which a portion of the data from the page unit of memory cells connected to a selected word line among the plurality of word lines is read and then stored in the buffer, and the memory controller is configured to cause the nonvolatile semiconductor memory to perform the second read operation when data at a target physical address of a read request can be read in a single second read operation.

Hereinafter, semiconductor memory devices according to example embodiments will be described with reference to the drawings. In the description presented below, the same reference numeral is assigned to elements having the same function or the same configuration.

### First Embodiment

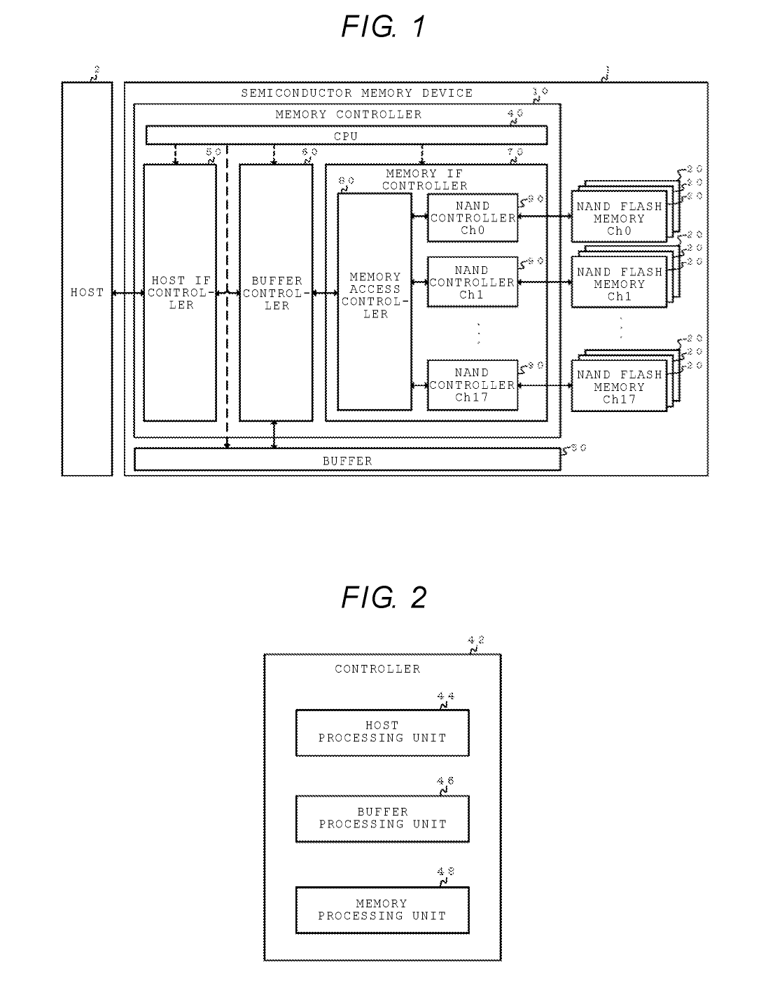

FIG. 1 is a block diagram of a semiconductor memory device according to a first embodiment.

The semiconductor memory device 1 can communicate with a host 2. The semiconductor memory device 1 includes a memory controller 10, a plurality of nonvolatile semiconductor memories 20, and a buffer 30. In description presented below, functional blocks necessary for writing data into the nonvolatile semiconductor memory 20 will not be described.

The memory controller 10 communicates with the host 2 and controls the overall operation of the semiconductor memory device 1. The memory controller 10 is a semiconductor integrated circuit, for example, configured as a system-on-a-chip (SoC).

In the description of this first embodiment, the host 2 is a computer that supports an interface of a serial ATA (SATA) specification; however, the host 2 may also be a computer that supports an interface of any other specification such as a serial attached SCSI (SAS) specification or an NVM Express® (NVMe) specification.

Each nonvolatile semiconductor memory 20 stores data in a nonvolatile manner. While the nonvolatile semiconductor memory 20 according to the present embodiment is a NAND flash memory, the nonvolatile semiconductor memory 20 may be a nonvolatile semiconductor memory of another type such as a three-dimensional structure flash memory, a NOR-type flash memory, or a magnetoresistive random access memory (MRAM). In the description presented below, the nonvolatile semiconductor memory 20 may be referred to as a NAND flash memory 20 in some instances.

The semiconductor memory device 1 according to the first embodiment includes NAND flash memories 20 for 18 different channels (Ch). The memory controller 10 can control the NAND flash memories 20 connected to these channels in parallel. A plurality of NAND flash memories 20 (in other words, a plurality of memory chips) may be connected to each channel. Hereinafter, the NAND flash memories 20 connected to the channels will be denoted as NAND flash memories Ch0 to Ch17. The number of the channels may be more than or less than 18 and is not a particular limitation.

The buffer 30 stores data in a volatile manner and temporarily. The data stored in the buffer 30 include: (1) data received from the host 2; (2) data read from the NAND flash memory 20; (3) information that is necessary for the memory controller 10 to control the semiconductor memory device 1, and the like.

While the buffer 30 according to this first embodiment is a dynamic random access memory (DRAM), the buffer 30 may be a volatile semiconductor memory of another type such as a static random access memory (SRAM). The buffer 30 may be in the memory controller 10.

The memory controller 10 includes a central processing unit (CPU) 40, a host interface (IF) controller 50, a buffer controller 60, and a memory interface (IF) controller 70.

The CPU 40 performs overall control of the semiconductor memory device 1 based on firmware (FW). FIG. 2 illustrates various functional units realized by the CPU 40 executing the firmware. The CPU 40 functions as a processing unit 42 that performs overall control of the semiconductor memory device 1. The processing unit 42 includes a host processing unit 44, a buffer processing unit 46, and a memory processing unit 48. The host processing unit 44 primarily controls the host IF controller 50. The buffer processing unit 46 primarily controls the buffer controller 60. The memory processing unit 48 primarily controls the memory IF controller 70.

The CPU 40 may be a separate semiconductor integrated circuit (chip) and is not required to be built in the memory controller 10. In the description presented below, a part or the whole of functions to be performed by executing the FW may be performed by dedicated hardware (HW), and a part or the whole of functions to be performed by the HW may be performed by the FW.

The description will be continued with reference back to FIG. 1.

The host interface (IF) controller 50 performs an analysis, execution, and the like of a command received from the host 2. The buffer controller 60 performs control of writing data into the buffer 30 and control of reading data, management of a vacant area of the buffer 30, and the like.

The memory IF controller 70 includes a memory access controller 80 and a plurality of NAND controllers 90. The memory access controller 80 controls commands and addresses that are necessary for an access to the nonvolatile semiconductor memory 20. The NAND controllers 90 are respectively connected to the NAND flash memories Ch0 to Ch17 (hereinafter, may be referred to as the NAND controllers Ch0 to Ch17). Each NAND controller 90 issues a command to the NAND flash memory 20 and controls operations such as write, read, erase and the like of data. The NAND controller 90 includes an error correction code (ECC) controller that is not specifically illustrated in FIG. 1. The ECC controller attaches an error correction code (ECC) to data written into the NAND flash memory 20. As the error correction code (ECC), for example, a Bose Chaudhuri Hocquenghem (BCH) code, a Low Density Parity Check (LDPC) code, or the like may be used. The ECC controller performs an error correction process for data read from the NAND flash memory 20 based on the error correction code (ECC).

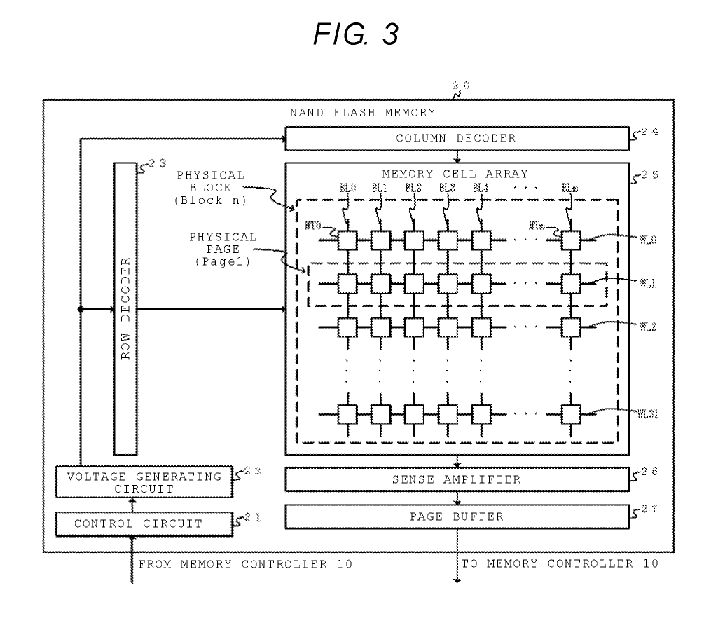

Next, the configuration of the NAND flash memory 20 according to the present embodiment will be described with reference to FIGS. 3 to 5.

As illustrated in FIG. 3, the NAND flash memory 20 includes: a control circuit 21, a voltage generating circuit 22, a row decoder 23, a column decoder 24, a memory cell array 25, a sense amplifier 26, and a page buffer 27.

The control circuit 21 is configured to control the voltage generating circuit 22 and the row decoder 23 and the column decoder 24 in accordance with an input signal from the memory controller 10.

The voltage generating circuit 22 is configured to generate voltages of predetermined levels such as a write voltage, an erase voltage, and a read voltage under the control of the control circuit 21.

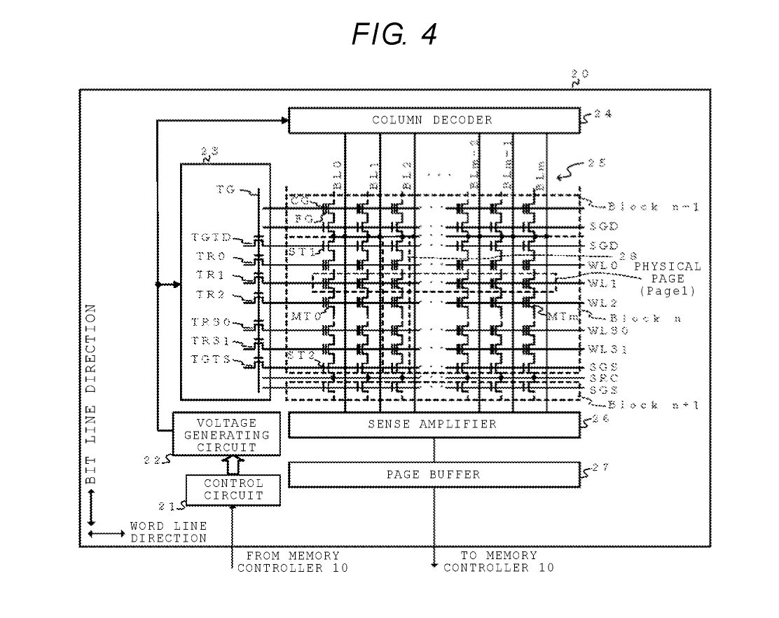

The row decoder 23 is configured to select one of word lines WL0 to WL31 and selection gate lines SGD and SGS in accordance with an address designated by the memory controller 10. As illustrated in FIG. 4, the row decoder 23 includes transfer gate transistors TGTD and TGTS having gates commonly connected to a transfer gate line TG and transfer transistors (high-voltage system transistors) TR0 to TR31.

Each of the transistors TR0 to TR31 applies a predetermined voltage such as an erase voltage or a write voltage to a control electrode CG of a memory cell transistor MT.

The memory cell array 25 includes a plurality of physical blocks (Block n−1, Block n, Block n+1, . . . ).

In the present embodiment, the NAND flash memory 20 is used as a single-level cell NAND flash memory that stores data of one bit in each memory cell transistor MT. However, the NAND flash memory 20 may be used as a multi-level cell NAND flash memory that stores data of multiple bits in each memory cell transistor MT.

As illustrated in FIG. 3, Block n includes a plurality of memory cell transistors MT0 to MTm arranged in a matrix pattern at the intersections between the word lines WL0 to WL31 and bit lines BL0 to BLm.

Each of the memory cell transistors MT0 to MTm has a stacked structure including a tunnel insulating film disposed on a semiconductor substrate, a floating electrode FG disposed on the tunnel insulating film, an inter-gate insulating film disposed on the floating electrode FG, and a control electrode CG disposed on the inter-gate insulating film. The memory cell transistors MT adjacent to each other along a bit line BL direction share a source/drain, which is a current path, and, in this example, 32 memory cell transistors MT are arranged such that one ends and the other ends of current paths are connected in series.

The memory cell transistors MT in which one end and the other end of the current path are connected in series and selection transistors S1 and S2 form a NAND cell column 28. The selection transistors ST1 and ST2 select this NAND cell column 28. One end of the current path of the NAND cell column 28 is connected to the sense amplifier 26, and the other end of the current path is connected to a source line SRC.

Here, the number of the memory cell transistors MT is not limited to 32 but, for example, may be 8, 16, or the like. In addition, only one of the selection transistors ST1 and ST2 may be required so long as the configuration permits the NAND cell column 28 to be selected.

The control electrodes CG of the memory cell transistors MT0 to MTm disposed in each word line WL direction (row direction) are commonly connected to one of the word lines WL0 to WL31. The gates of the selection transistors ST1 are commonly connected to the selection gates SGS, and the gates of the selection transistors ST2 are commonly connected to the selection gates SGD. The source of the selection transistor S1 is connected to the source line SRC, and the drain of the selection transistor ST2 is connected to one of the bit lines BL0 to BLm.

For each of the word lines WL0 to WL31, one or a plurality of page addresses is assigned. Here, for the convenience of description, it is assumed that one page address is assigned to each word line. As illustrated inside broken lines in FIGS. 3 and 4, one physical page is formed by each of the word lines WL0 to WL31. For example, a physical page Page1 is formed in correspondence with the word line WL1. This physical page is a minimum unit for data writing and data reading. An erase operation is performed simultaneously on the several physical pages of one physical block (which is the minimum unit of erasing).

The sense amplifier 26 is configured to amplify data for each page read from the bit lines BL0 to BLm and store the read data in the page buffer 27. The data stored in the page buffer 27 are output to the memory controller 10.

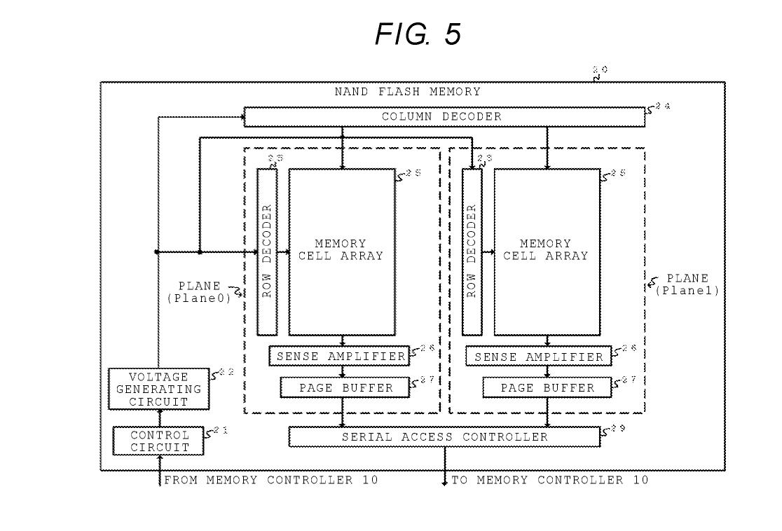

The NAND flash memory 20 may include a plurality of planes. FIG. 5 illustrates a configuration of the NAND flash memory 20 that includes two planes Plane0 and Plane1. However, the number of planes included in the NAND flash memory 20 is not particularly limited to two. One plane includes a row decoder 23, a memory cell array 25, a sense amplifier 26, and a page buffer 27. The planes share the output of the voltage generating circuit 22 and the output of the column decoder 24. In addition, data output from the page buffer 27 of each plane is output to the memory controller 10 through the serial access controller 29. The memory controller 10 can control the planes in parallel.

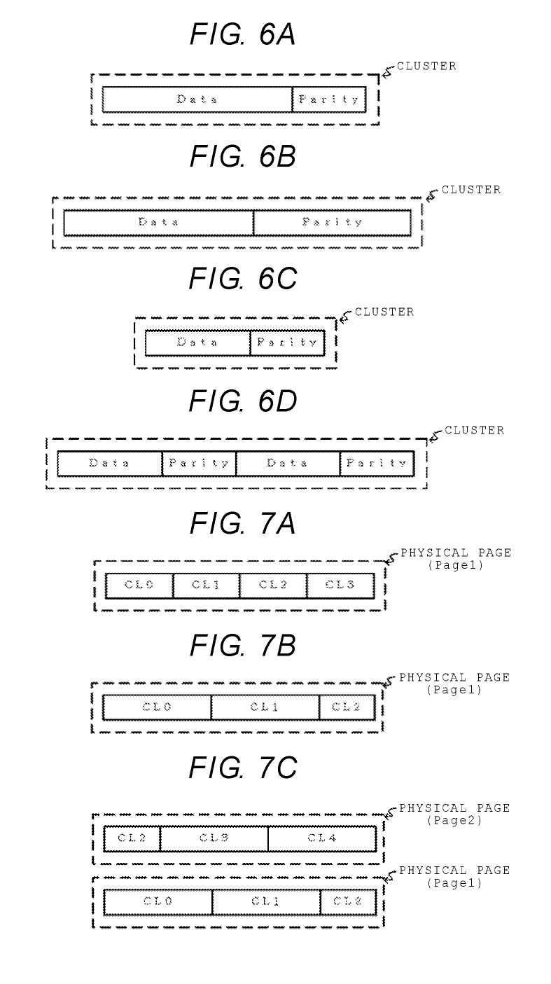

Next, a cluster, which is a logical unit by which the memory controller 10 manages data, will be described with reference to FIGS. 6A to 6D.

As illustrated in FIG. 6A, one cluster includes data and parity information. The parity information is an error correction code (ECC) for the data. The parity information may also be an error detection code for the data.

As illustrated in FIGS. 6A to 6C, the sizes of clusters need not be the same across the whole of semiconductor memory device. For example, for data which needs high correction capability, the size of parity information may be increased for a fixed size of the data, as illustrated in FIGS. 6A and 6B. Alternatively, as illustrated in FIGS. 6A and 6C, the size of data may be decreased with the size of parity information being fixed. Each cluster, as illustrated in FIG. 6D, may include a plurality of sets of data and parity information.

The cluster need not include parity information in some instances. Alternatively, in addition to data and parity information, the cluster may include a pad for adjusting the size of information in the cluster.

Next, an example of the sizes of clusters and a physical page will be described with reference to FIGS. 7A to 7C.

FIG. 7A illustrates a state in which clusters CL0 to CL3 (each having a same size) are stored in one physical page Page1. In other words, in the arrangement illustrated in FIG. 7A, an integer multiple (here, four times) of the size of the individual clusters stored in the physical page is the size of the physical page.

On the other hand, in FIG. 7B, two clusters CL0 and CL1 and a smaller sized cluster CL2 are stored in the physical page Page1. In such a case, for example, a first half of the data CL2 is stored in physical page Page1, and a second half of the data CL2 is stored in a different physical page (Page2), as illustrated in FIG. 7C. In the arrangement illustrated in FIG. 7C, the size of the physical page is 2.5 times the size of a full cluster (e.g., CL0 or CL1) or five times the size of the split cluster CL2.

However, a relationship between the size of the clusters and the size of the physical page is not limited to the examples illustrated in FIGS. 7A to 7C. In addition, the relationship between the size of the clusters and the size of the physical page need not be the same in all portions of the semiconductor memory device 1. In other words, a relationship between the size of the clusters and the size of the physical page may be different, for example, for each logical block or each logical page.

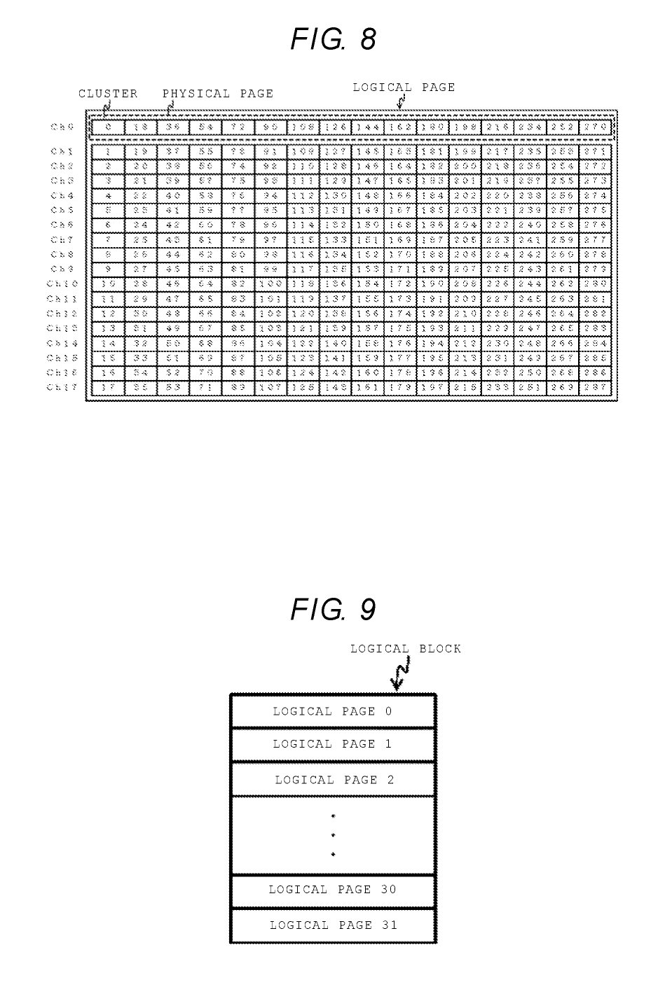

Next, a logical page will be described with reference to FIG. 8. The memory controller 10 manages data on the NAND flash memory 20 in units of one logical page.

In FIG. 8, each table cell corresponds to a cluster. One row (16 clusters) aligned in the horizontal direction, which corresponds to one of the NAND flash memories 20, corresponds to a physical page. In other words, in the example illustrated in FIG. 8, one physical page includes 16 clusters. In addition, each logical page includes one physical page on each channel and thus includes a total of 18 physical pages.

A number called a logical cluster address is assigned to each cluster. The logical cluster addresses are assigned such that the logical cluster address of a first cluster of the NAND flash memory Ch0 is 0, the logical cluster address of a first cluster of the NAND flash memory Ch1 is 1, and the like. In addition, the logical cluster addresses are assigned such that the logical cluster address of a first cluster of the NAND flash memory Ch17 is 17, the logical cluster address of a second cluster of the NAND flash memory Ch0 is 18, and the like. The position of each cluster within a logical page is specified by the logical cluster address.

Next, a logical block will be described with reference to FIG. 9. The memory controller 10 controls erase of data from the NAND flash memory 20 by using the logical block corresponding to 32 logical pages of data as a logical unit. In other words, the memory controller 10 performs an erase process of data not for each physical block, which is a minimal unit of erase of the data in the NAND flash memory 20, but for each logical block.

As above, the whole configuration of the semiconductor memory device 1 according to the present embodiment, the configuration of the NAND flash memory 20, the management unit of data according to the memory controller 10, and the like have been described. Hereinafter, reading of data from the NAND flash memory 20 will be described.

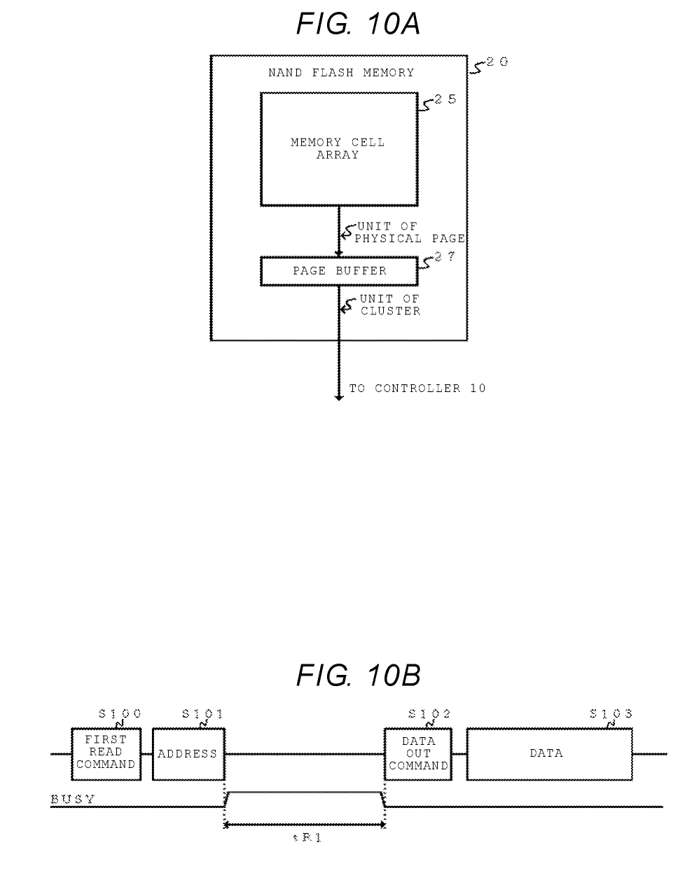

First, a first read operation will be described with reference to FIGS. 10A and 10B.

FIG. 10A illustrates a flow of data according to the first read operation. In FIG. 10A, among the functional blocks of the NAND flash memory 20, functional blocks other than the memory cell array 25 and the page buffer 27 are not illustrated.

In the first read operation, the NAND flash memory 20 reads data in units of one physical page from the memory cell array 25 and stores the read data in the page buffer 27. In other words, the NAND flash memory 20 reads data stored in the memory cell transistors MT0 to MTm connected to a word line corresponding to a page address of a read target and stores this read data in the page buffer 27. The NAND flash memory 20 outputs the data stored in the page buffer 27 to the memory controller 10 in units of clusters.

FIG. 10B is a timing chart of the first read operation.

The memory controller 10 issues a first read command to request the NAND flash memory 20 to perform the first read operation (S100). Next, the memory controller 10 inputs an address of a read target to the NAND flash memory 20 (S101). The NAND flash memory 20 reads data of the target from the memory cell array 25 for a time tR1 and stores the read data in the page buffer 27. During this period, the NAND flash memory 20 asserts a Busy signal to the memory controller 10.

When the Busy signal is negated, the memory controller 10 issues a data output command to the NAND flash memory 20 (S102). The NAND flash memory 20 that has received the data out command outputs data stored in the page buffer 27 to the memory controller 10 (S103).

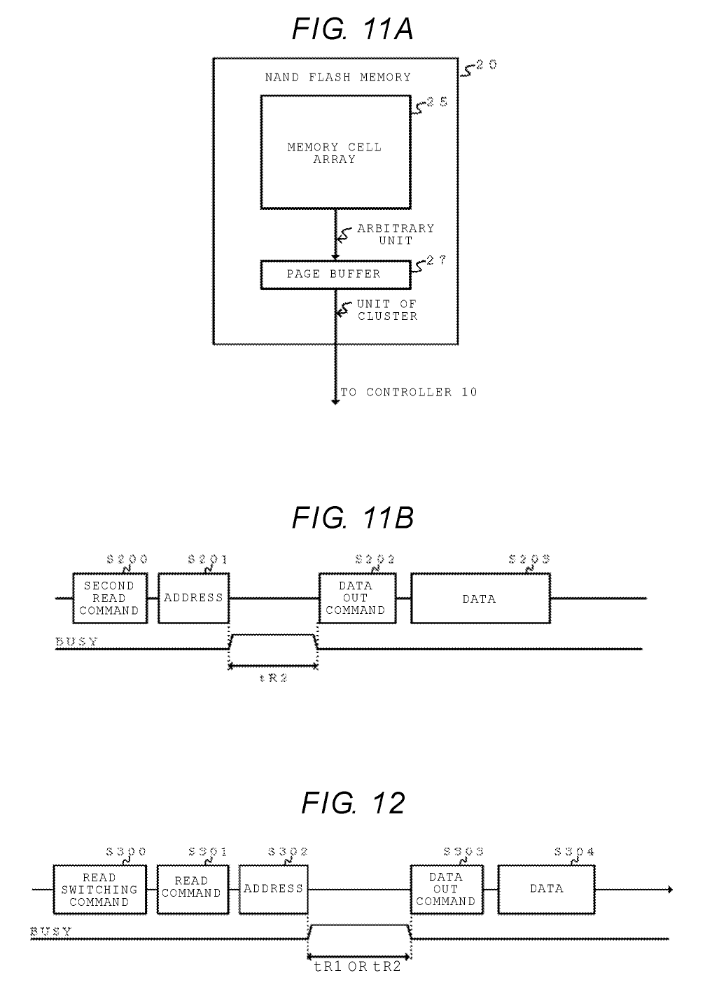

Next, a second read operation will be described with reference to FIGS. 11A and 11B.

FIG. 11A illustrates the flow of data according to the second read operation. Also in FIG. 11A, among the functional blocks of the NAND flash memory 20, functional blocks other than the memory cell array 25 and the page buffer 27 are not illustrated.

In the second read operation, the NAND flash memory 20 reads data in an arbitrary unit, which may be less than the size of a physical page and at least the size of a cluster, from the memory cell array 25 and stores the read data in the page buffer 27. In other words, the NAND flash memory 20 reads data stored in an arbitrary memory cell transistor from among the memory cell transistors MT0 to MTm, which are connected to a word line, corresponding to a page address of a read target and stores the read data in the page buffer 27. The NAND flash memory 20 outputs the data stored in the page buffer 27 to the memory controller 10 in units of one cluster.

FIG. 11B is a timing chart of the second read operation.

The memory controller 10 issues a second read command to request the NAND flash memory 20 to perform the second read operation (S200). Next, the memory controller 10 inputs an address of a read target to the NAND flash memory 20 (S201). The NAND flash memory 20 reads data of the target from the memory cell array 25 for a time tR2 and stores the read data in the page buffer 27. During this period, the NAND flash memory 20 asserts a Busy signal to the memory controller 10. Here, the time tR2 is shorter than the time tR1.

When the Busy signal is negated, the memory controller 10 issues a data output command to the NAND flash memory 20 (S202). The NAND flash memory 20 that has received the data out command outputs data stored in the page buffer 27 to the memory controller 10 (S203).

The switching between the first read operation and the second read operation, as illustrated in FIG. 12, may be performed using a read switching command. The memory controller 10 issues a read switching command and notifies the NAND flash memory 20 whether a read command issued therefrom requests the first read operation or the second read operation (S300). Next, the memory controller 10 issues a read command (S301). The NAND flash memory 20 performs a read operation designated by the read switching command (S302 to S304).

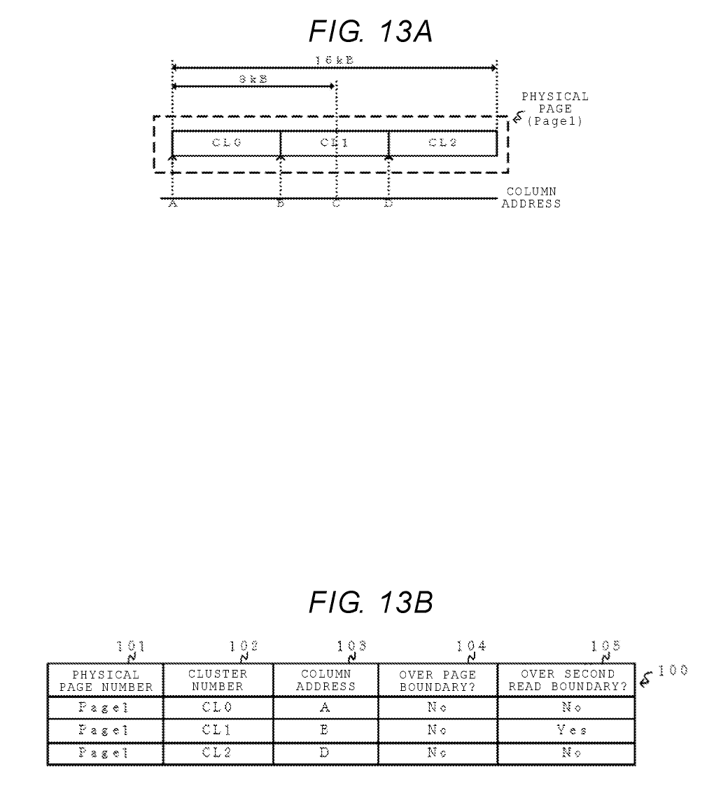

Next, an example of a read operation will be described with reference to FIGS. 13A and 13B.

As illustrated in FIG. 13A, in this example, three clusters CL0 to CL2 are arranged in one physical page Page1. The cluster CL0 is arranged from a column address=A. The cluster CL1 is arranged from a column address=B. The cluster CL2 is arranged from a column address=D. Here, the size of the physical page is 16 kB, and the unit for reading in the second read operation is 8 kB. It is assumed that the second read operation can be performed from the start (column address=A) of the physical page or the middle of the physical page, in other words, a position (column address=C) of 8 kB from the start.

To read the cluster CL0, the memory controller 10 requests the NAND flash memory 20 to perform the second read operation. The reason for this is that the second read operation can be performed at a speed higher than that of the first read operation. At this time, the memory controller 10 designates a column address=A of the page Page1. The NAND flash memory 20 performs the second read operation from the column address=A to include the cluster CL0 arranged at the column address=A.

To read the cluster CL1, the memory controller 10 requests the NAND flash memory 20 to perform the first read operation. The reason for this is that the cluster CL1 cannot be read in just one second read operation. At this time, the memory controller 10 designates a column address=B of the page Page1. The NAND flash memory performs the first read operation from the column address=A to include the cluster CL1 arranged at the column address=B.

To read the cluster CL2, the memory controller 10 requests the NAND flash memory 20 to perform the second read operation. The reason for this is that the second read operation can be performed at a speed higher that the speed of the first read operation. At this time, the memory controller 10 designates a column address=D of the page Page1. The NAND flash memory performs the second read operation from the column address=C to include the cluster CL2 arranged at the column address=D.

FIG. 13B illustrates a configuration of a cluster arrangement management table 100 that is used to manage the cluster arrangement within a physical page. The cluster arrangement management table 100, as will be described below, is stored in the memory access controller 80. The cluster arrangement management table 100 manages a physical page number 101, a cluster number 102, a column address 103, a flag 104 representing whether or not the cluster extends over a page boundary, and a flag 105 representing whether or not the cluster extends over a second read boundary. The column address 103 represents the column address of the start of each cluster. The flag 104 represents whether or not the end of each cluster is present within the same physical page as its start. The flag 105 represents whether or not each cluster can be fully read by one second read operation.

The content represented with the cluster arrangement management table 100 illustrated in FIG. 13B corresponds to the cluster arrangement illustrated in FIG. 13A. The cluster of the cluster number=CL0 is arranged from the column address=A of the physical page number=Page1. The cluster CL0 neither extends over the page boundary nor over the second read boundary. The cluster of the cluster number=CL1 is arranged from the column address=B of the physical page number=Page1. The cluster CL1 does not extend over the page boundary but extends over the second read boundary. The cluster of the cluster number=CL2 is arranged from the column address=D of the physical page number=Page1. The cluster CL2 neither extends over the page boundary nor over the second read boundary.

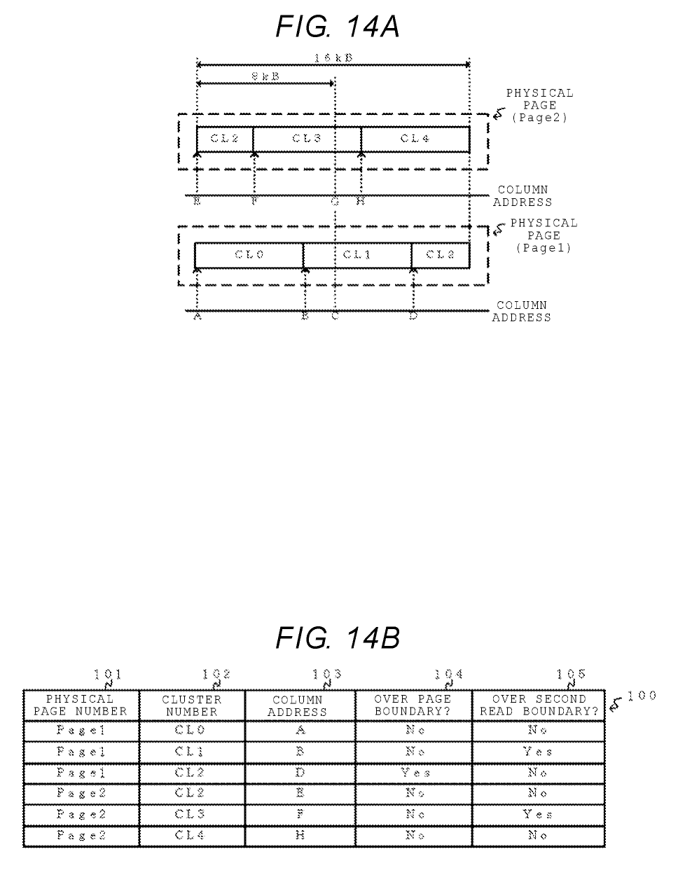

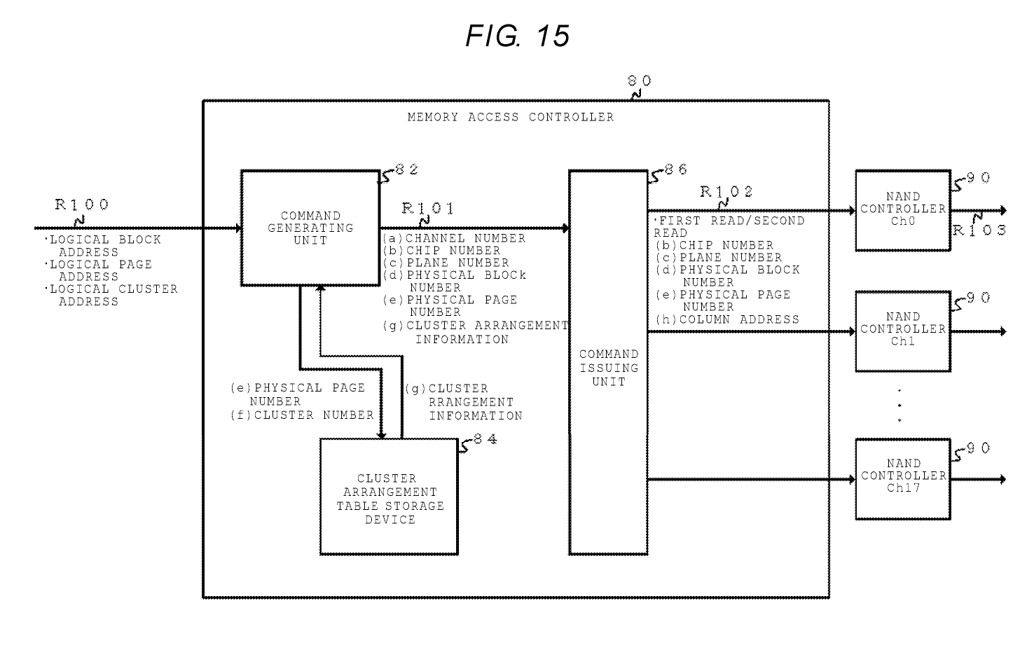

Next, another example of the read operation will be described with reference to FIGS. 14A and 14B.

As illustrated in FIG. 14A, in this example, five clusters CL0 to CL4 are arranged in two physical pages, Page1 and Page2. The cluster CL0 begins at a column address=A of the page Page1. The cluster CL1 begins at a column address=B of the page Page1. The cluster CL2 begins at a column address=D of the page Page1; however, the cluster CL2 is not entirely disposed in the page Page1. A second half of this cluster CL2 begins at a column address=E of the page Page2. The cluster CL3 begins at a column address=F of the page Page2. The cluster CL4 begins at a column address=H of the page Page2.

Also in this example, the size of each physical page is 16 kB, and the unit for reading in the second read operation is 8 kB. It is assumed that the second read operation can be performed from the start (the column address=A in the case of the page Page1 and the column address=E in the case of the page Page2) or the middle of the physical page. Here, the middle of the physical is a position of 8 kB from the start of the physical page (e.g., the column address=C for the page Page1 or the column address=G in for the page Page2).

When the cluster CL0 is to be read, the memory controller 10 requests the NAND flash memory 20 to perform the second read operation. The reason for this request is that the second read operation can be performed at a speed higher than the first read operation. At this time, the memory controller 10 designates a column address=A of the page Page1. The NAND flash memory 20 performs the second read operation from the column address=A to include the cluster CL0 beginning at the column address=A.

When the cluster CL1 is to be read, the memory controller 10 requests the NAND flash memory 20 to perform the first read operation. The reason for this request is that the cluster CL1 cannot be read with just one second read operation (one 8 kB increment of the physical page). At this time, the memory controller 10 designates a column address=B of the page Page1. The NAND flash memory performs the first read operation (16 kB increment or the entire physical page length) from the column address=A to include the cluster CL1 beginning at the column address=B.

When the cluster CL2 is to be read, the memory controller 10 requests the NAND flash memory 20 to perform the second read operation. At this time, the memory controller 10 designates a column address=D of the page Page1. The NAND flash memory performs the second read operation from the column address=C to include the cluster CL2 portion beginning at the column address=D.

In addition, the memory controller 10 requests the NAND flash memory 20 to perform the second read operation for a second time because the cluster CL2 extends over parts of both the pages Page1 and Page2. At this time, the memory controller 10 designates a column address=E of the page Page2. The NAND flash memory performs the second read operation from the column address=E to include the cluster CL2 portion beginning at the column address=E.

In addition, the cluster CL2 can be read also by two first read operations, that is one first read operation designating the column address=D of the page Page1 and another first read operation designating the column address=E of the page Page2.

When the cluster CL3 is to be read, the memory controller 10 requests the NAND flash memory 20 to perform the first read operation. The reason for this request is that the cluster CL3 cannot be read in just one second read operation. At this time, the memory controller 10 designates a column address=F of the page Page2. The NAND flash memory performs the first read operation from the column address=E to include the cluster CL3 beginning at the column address=F.

When the cluster CL4 is to be read, the memory controller 10 requests the NAND flash memory 20 to perform the second read operation. At this time, the memory controller 10 designates a column address=H of the page Page2. The NAND flash memory performs the second read operation from the column address=G to include the cluster CL4 beginning at the column address=H.

A content represented by the cluster arrangement management table 100 illustrated in FIG. 14B corresponds to the cluster arrangement illustrated in FIG. 14A.

The cluster corresponding to the cluster number=CL0 is arranged from the column address=A of the physical page number=Page1. This cluster CL0 neither extends over the page boundary nor over the second read boundary. The cluster corresponding to the cluster number=CL1 is arranged from the column address=B of the physical page number=Page1. This cluster CL1 does not extend over the page boundary but extends over the second read boundary. The cluster corresponding to the cluster number=CL2 is arranged from the column address=D of the physical page number=Page1. This cluster CL2 extends over the page boundary but does not extend over the second read boundary.

A second half of the cluster corresponding to the cluster number=CL2 begins at the column address=E of the physical page number=Page2. This second half of the cluster CL2 neither extends over the page boundary nor over the second read boundary. The cluster corresponding to the cluster number=CL3 begins at the column address=F of the physical page number=Page2. This cluster CL3 does not extend over the page boundary but does extend over the second read boundary. The cluster number=CL4 begins at the column address=H of the physical page number=Page2. This cluster CL4 neither extends over the page boundary nor over the second read boundary.

Next, a detailed configuration of the memory access controller 80 will be described with reference to FIG. 15.

The memory access controller 80 includes a command generating unit 82, a cluster arrangement table storage device 84, and a command issuing unit 86.

A read request R100 is input from the memory processing unit 48 (see FIG. 2) to the command generating unit 82. The read request R100 includes a logical block address, a logical page address, and a logical cluster address. The logical block address specifies a logical block. The logical page address specifies a logical page within the logical block. The logical cluster address, as described above, specifies a cluster in the logical page.

The command generating unit 82 translates the logical block address, the logical page address, and the logical cluster address into a corresponding physical address, for example, by using a physical-logical translation table (not specifically illustrated in FIG. 15). The physical address includes (a) a channel (channel number), (b) a memory chip (chip number) in the channel, (c) a plane (plane number) in the memory chip, (d) a physical block (physical block number) in the plane, (e) a physical page (physical page number) within the physical block, and (f) a cluster (cluster number) in the physical page.

The command generating unit 82 inputs (e) a physical page number and (f) a cluster number to the cluster arrangement table storage device 84. The cluster arrangement table storage device 84 stores the cluster arrangement table 100. The cluster arrangement table storage device 84 provides (g) cluster arrangement information by searching the cluster arrangement table 100 based on the physical page number and the cluster number. The cluster arrangement information includes (h) a column address 103, (i) a flag 104 representing whether or not the cluster extends over the page boundary, and (j) a flag 105 representing whether or not the cluster extends over the second read boundary. The cluster arrangement table storage device 84 inputs the cluster arrangement information to the command generating unit 82.

The command generating unit 82 then inputs a read request R101 to the command issuing unit 86. The read request R101 includes (a) a channel number, (b) a chip number, (c) a plane number, (d) a physical block number, (e) a physical page number, and (g) cluster arrangement information.

The command issuing unit 86 generates a first read request or a second read request based on the read request R101. An algorithm for generating either the first read request or the second read request will be described later. The command issuing unit 86 inputs the generated first read request or the generated second read request (read request R102) to the NAND controller 90 corresponding to a channel designated with the channel number. The read request R102 includes (b) a chip number, (c) a plane number, (d) a physical block number, (e) a physical page number, and (h) a column address.

The NAND controller 90 converts the read request R102 into a command R103 that is compliant with an interface specification for the NAND flash memory 20 and issues the command R103 to the NAND flash memory 20.

Next, the sequence of generation of the read request R102 by the command issuing unit 86 will be described with reference to FIG. 16.

When a read request R101 is received, the command issuing unit 86 determines whether or not a targeted (addressed) cluster of a read target extends over the second read boundary based on the cluster arrangement information (S400). In a case where the cluster of the read target extends over the second read boundary (S400: Yes), the command issuing unit 86 generates the first read request as the read request R102 (S401). On the other hand, in a case where the cluster of the read target does not extend over the second read boundary (S400: No), the command issuing unit 86 generates the second read request as the read request R102 (S402).

In addition, the command issuing unit 86 also determines whether or not the cluster of the read target extends over the page boundary based on the cluster arrangement information (S403). In a case where the cluster extends over the page boundary (S403: Yes), the command issuing unit 86, determines whether or not the cluster of the read target extends over the second read boundary (S400) in order to generate another read request R102 to read the remaining, unread portion of the targeted cluster.

According to the semiconductor memory device of the first embodiment, since the read request is changed according to the arrangement of the cluster corresponding to the read target within the physical page(s), the read performance of the semiconductor memory device can be improved.

### Second Embodiment

In a second embodiment, the read request is further changed according to the sequentiality of a read request.

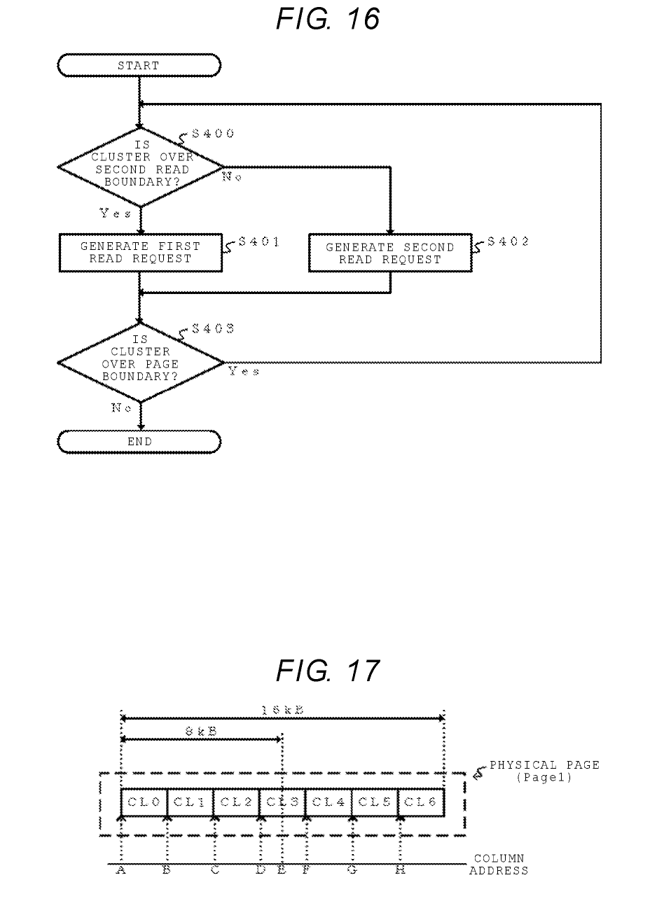

FIG. 17 illustrates an example of a read operation according to the second embodiment.

As illustrated in FIG. 17, seven clusters (CL0 to CL6) are arranged in one physical page Page1. A cluster CL0 begins at a column address=A. A cluster CL1 begins at a column address=B. A cluster CL2 begins at a column address=C. A cluster CL3 begins at a column address=D. A cluster CL4 begins at a column address=F. A cluster CL5 begins at a column address=G. A cluster CL6 begins at a column address=H.

The size of the physical page is 16 kB, and the unit for reading in the second read operation is 8 kB. It is assumed that the second read operation can be performed from the start of the physical page (the column address=A) or the middle of the physical page, in other words, a position of 8 kB from the page start (the column address=E).

According to the condition for generating a read request as described in the first embodiment, the second read request is generated for individually reading any of the clusters CL0, CL1, CL2,CL4, CL5, and CL6. On the other hand, the first read request would be generated for reading the cluster CL3 according to the first embodiment.

Here, an example case will be described in which data of the cluster CL5 is to be read immediately after the reading of the data of the cluster CL1. Under the processing described for the first embodiment, two separate second read requests would be generated (one second read request for reading the cluster CL1 and another second read request for reading the cluster CL5). On the other hand, a memory access controller 80 according to the second embodiment generates just one first read request in such a case. The reason for this is that one first read request can be performed faster than two separate second read requests.

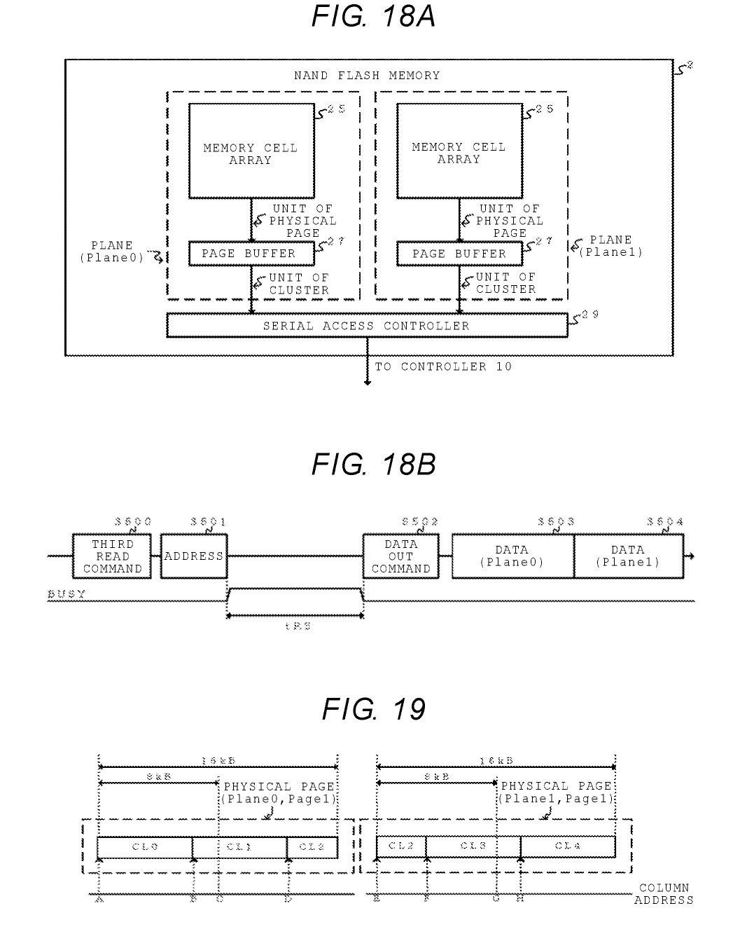

Next, another example of a read operation according to the second embodiment will be described with reference to FIGS. 18A to 20.

First, a third read operation will be described with reference to FIGS. 18A and 18B.

FIG. 18A describes the flow of data according to the third read operation. In the case illustrated in FIG. 18A, a NAND flash memory 20 includes two planes Plane0 and Plane1. In FIG. 18A, among the functional blocks of the NAND flash memory 20, functional blocks other than a memory cell array 25, a page buffer 27, and a serial access controller 29 are not illustrated.

In the third read operation, the NAND flash memory 20 reads data in units of one physical page from a memory cell array 25 of each plane and stores the read data in each page buffer 27. In other words, the NAND flash memory 20 reads data stored in memory cell transistors MT0 to MTm, which are connected to a word line, corresponding to a page address of a read target and then stores the read data in the page buffer 27. The operations for reading data from memory cell arrays 25 of the planes Plane0 and Plane1 are simultaneously performed. The NAND flash memory 20 outputs the data stored in the page buffer 27 for each plane in units of clusters to the memory controller 10 through the serial access controller 29.

FIG. 18B is a timing chart of the third read operation.

The memory controller 10 issues a third read command to request the NAND flash memory 20 to perform the third read operation (S500). Next, the memory controller 10 inputs an address to the NAND flash memory 20 (S501). The NAND flash memory 20 reads data at the target address in memory cell array 25 of each plane during a time tR3 and stores the read data in the page buffer 27. During this period (tR3), the NAND flash memory 20 asserts a Busy signal to the memory controller 10. Here, the time tR3 required for the third read command is approximately the same as the time tR1 required for the first read command.

When the Busy signal is negated, the memory controller 10 issues a data output command to the NAND flash memory 20 (S502). The NAND flash memory 20 receiving the data out command outputs the data stored in the page buffer 27 of the plane Plane0 to the memory controller 10 (S503). Next, the NAND flash memory 20 outputs the data stored in the page buffer 27 of the plane Plane1 to the memory controller 10 (S504).

Next, another example of the read operation according to the present embodiment will be described with reference to FIG. 19.

As illustrated in FIG. 19, five clusters CL0 to CL4 are in corresponding physical pages of two mutually-different planes (e.g., the page Page1 of the plane Plane0 and a page Page1 of the plane Plane1). The cluster CL0 begins at a column address=A of the page Page1 of the plane Plane0. The cluster CL1 begins at a column address=B of the page Page1 of the plane Plane0. While the cluster CL2 begins at a column address=D of the page Page1 of the plan Plane0, the whole cluster CL2 is not stored in the page Page1 of the plane Plane0. A second half of the cluster CL2 begins at a column address=E of the page Page1 of the plane Plane1. The cluster CL3 begins at a column address=F of the page Page1 of the plane Plane1. The cluster CL4 begins at a column address=H of the page Page1 of the plane Plane1.

Also, in this example, the size of the physical page is 16 kB, and the unit for reading in the second read operation is 8 kB. It is assumed that the second read operation can be performed from the start of a physical page (the column address=A in the case of the page Page1 of the plane Plane0 and the column address=E in the case of the page Page1 of the plane Plane1) or the middle (8 kB from the start) of the physical page (the column address=C in the case of the page Page1 of the plane Plane0 and the column address=G in the case of the page Page1 of the plane Plane1).

According to the condition for generating the read request described in the first embodiment, one second read request is generated for each of the clusters CL0 and CL4. In addition, one first read request is generated for each of the clusters CL1 and CL3. For the cluster CL2, two second read requests are generated.

Here, for example, a case will be described in which the data of the cluster CL4 is read immediately after the reading of the data of the cluster CL0. In the first embodiment, two second read requests including a second read request for the cluster CL0 and a second read request for the cluster CL4 would be generated. On the other hand, the memory access controller 80 according to the second embodiment generates, instead, one third read request in such a case. The reason for this is that a single third read request can be performed at a speed higher than that of two second read requests.

The memory access controller 80 according to second embodiment also generates the third read request for the cluster CL2. Again, the reason for this is that one third read request can be performed at a speed higher than that of two second read requests.

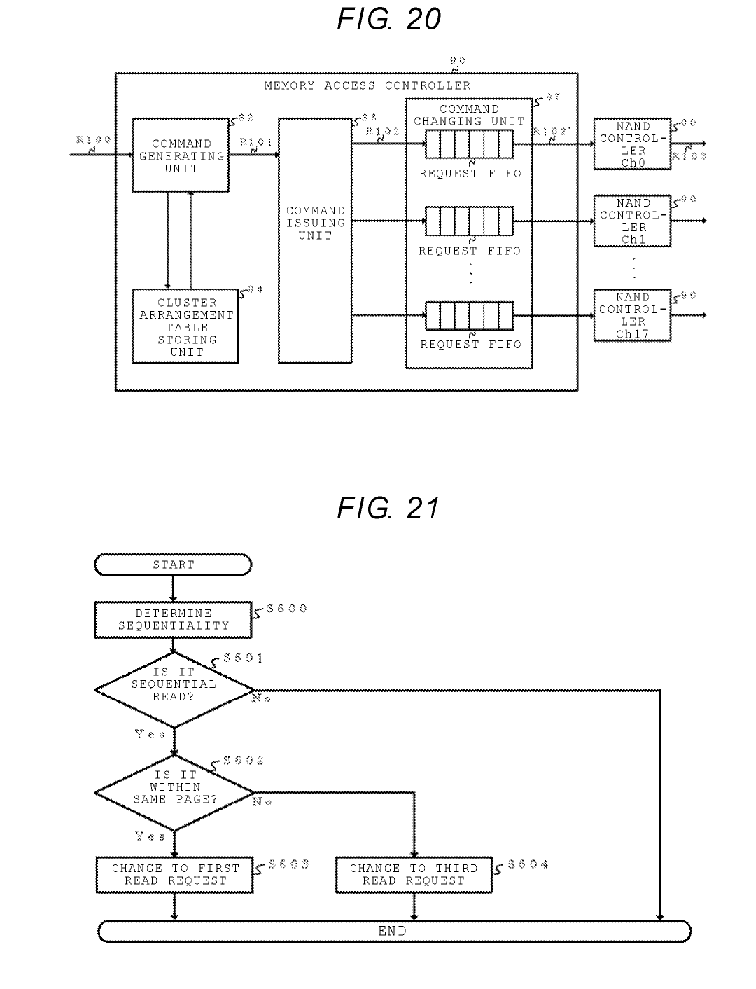

Next, the memory access controller 80 will be described with reference to FIG. 20.

The memory access controller 80 according to the second embodiment includes a command changing unit 87 in addition to the configuration of the memory access controller 80 described according to the first embodiment.

The command changing unit 87 includes a request FIFO for each channel. The request FIFO stores read requests R102. The request FIFO, for example, can store read requests R102 corresponding to a maximum number of clusters that can be arranged in two physical pages.

The command changing unit 87 searches for read requests R102 stored in the request FIFO of a channel. In a case where a plurality of second read requests targeted at clusters within a same physical page are stored in the request FIFO, the command changing unit 87 changes the second read requests to one first read request. In addition, when a plurality of first read requests or a plurality of second read requests arranged in corresponding physical pages of mutually-different planes are stored in the request FIFO, the command changing unit 87 changes the read requests to one third read request. The command changing unit 87 outputs the changed read request R102′ to the NAND controller 90.

A method of determining the sequentiality of read requests is not limited to the method described above. For example, the memory processing unit 48 may determine the sequentiality. In addition, the command changing unit 87 may include just one request FIFO instead of including a separate request FIFO for each channel.

Next, the sequence of generating a read request R102′ by the command issuing unit 86 and the command changing unit 87 will be described with reference to FIG. 21.

The command changing unit 87 searches the request FIFO and determines the sequentiality of read requests R102 (S600). In other words, it is determined whether (1) a plurality of second read requests targeted for a plurality of clusters that are stored within a same physical page (this case is referred to as a first case) or (2) a plurality of first read requests or second read requests are targeted for a plurality of clusters that are stored in corresponding physical pages of mutually-different planes (this case referred to as a second case).

When there is a sequentiality in the read requests R102 (S601: Yes) and these are targeted at clusters within a same physical page (S602: Yes) (i.e., the case is the first case), the command changing unit 87 generates a first read request as the read request R102′ (S603). When there is sequentiality in the read request R102 (S601: Yes) but no sequential reading of clusters within a same physical page (S602: No) (i.e., the case is the second case), the command changing unit 87 generates a third read request as the read request R102′ (S604).

On the other hand, when there is no sequentiality in the read requests R102, the command changing unit 87 does not change the read requests R102. In other words, the read request R102′ is the same as the read request R102.

According to the semiconductor memory device of the second embodiment described above, the read request can be further changed according to the arrangement of the targeted clusters within a physical page, and accordingly, the read performance of the semiconductor memory device can be improved.

According to the semiconductor memory devices of the embodiments described above, a read request can changed according to the arrangement of targeted cluster(s) within a physical page, and accordingly, the read performance of the semiconductor memory device can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a nonvolatile semiconductor memory including a plurality of memory cells in an array, a plurality of word lines each connected to a page unit of memory cells, and a buffer for temporarily storing data read from the plurality of memory cells; and
a memory controller connected to the nonvolatile semiconductor memory and configured to control reading of data from the plurality of memory cells, wherein
the nonvolatile semiconductor memory is configured to perform a first read operation in which all data from a page unit of memory cells connected to a selected word line among the plurality of word lines is read and then stored in the buffer, and a second read operation in which a portion of the data from the page unit of memory cells connected to a selected word line among the plurality of word lines is read and then stored in the buffer, and
the memory controller is configured to cause the nonvolatile semiconductor memory to perform the second read operation when data at a target physical address of a read request can be read in a single second read operation.

2. The semiconductor memory device according to claim 1, wherein the memory controller is configured to cause the nonvolatile semiconductor memory to perform the first read operation when data at the target physical address cannot be read by a single second read operation.

3. The semiconductor memory device according to claim 1, wherein the portion of the data from the page unit of memory cells connected the selected word line that is read in the second reading operation has a size of one-half of the page unit.

4. The semiconductor memory device according to claim 1, wherein the memory controller includes a command changing circuit including a request FIFO to store a plurality of read requests received in sequence, and the command changing circuit is configured to determine if the read requests received in sequence have target physical addresses within a same physical page such that the data associated with the read requests received in sequence can be read in a single first read operation, and if so, issue a modified read request combining the read requests received in sequence.

5. The semiconductor memory device according to claim 1, wherein
the nonvolatile semiconductor memory includes a plurality of planes, and
the memory controller is configured to cause the nonvolatile semiconductor memory to perform a third read operation for reading data in parallel from corresponding pages in the plurality of planes.

6. The semiconductor memory device according to claim 5, wherein the memory controller causes the nonvolatile semiconductor memory to perform the third read operation when data at the target physical address can be read using a single third read operation.

7. The semiconductor memory device according to claim 1, wherein a time required to complete the second read operation is less than a time required to complete the first read operation.

8. The semiconductor memory device according to claim 1, wherein the memory controller issues a first command to cause the nonvolatile semiconductor memory to perform the first read operation, and a second command, different from the first command, to cause the nonvolatile semiconductor memory to perform the second read operation.

9. The semiconductor memory device according to claim 1, wherein the memory controller issues:
a first command to designate a read operation type to be one of the first read operation and the second read operation, and
a second command to cause the nonvolatile semiconductor memory to perform a read operation according to the read operation type designated by the first command.

10. A method of controlling a semiconductor memory device, the semiconductor memory device including a nonvolatile semiconductor memory having a plurality of memory cells in an array, a plurality of word lines each connected to a page unit of memory cells, and a buffer for temporarily storing data read from the plurality of memory cells, the nonvolatile semiconductor memory being configured to perform a first read operation in which all data of a page unit of the memory cells is read and a second read operation in which a portion of the data of a page unit of the memory cells is read, the method comprising:
receiving a read data request to read data stored at a target physical address in the nonvolatile semiconductor memory; and
requesting the nonvolatile semiconductor memory to perform the second read operation when the data at the target address can be read by a single second read operation.

11. The method according to claim 10, further comprising:
requesting the nonvolatile semiconductor memory to perform the first read operation when the data at the target physical address cannot be read by a single second read operation.

12. The method of claim 10, further comprising:
requesting the nonvolatile semiconductor memory to perform at least one first read operation when the target physical address spans two physical pages in the nonvolatile semiconductor memory with a first portion of the data at the target physical address being on a first physical page and a second portion of the data at the target physical address being on a second physical page, and either of the first or second portions cannot be read in a single second read operation.

13. The method according to claim 10, wherein the second read operation reads data in one-half of a page-unit size.

14. The method according to claim 10, wherein the nonvolatile semiconductor memory includes a second array of memory cells and a second plurality of word lines each of which is connected to a page unit of memory cells in the second array, the method further comprising:
controlling the nonvolatile semiconductor memory to perform a third read operation for reading data in parallel from memory cells in a corresponding group of memory cells in the array and the second array.

15. A memory system, comprising:
a nonvolatile semiconductor memory including an array of memory cells and a plurality of word lines, each connected to a page unit of memory cells in the array, the nonvolatile semiconductor memory configured to perform a first read operation in which all data from a page unit of memory cells connected to a selected word line among the plurality of word lines is read then stored in a page buffer, and a second read operation in which only a portion of data from a page unit of memory cells connected to a selected word line among the plurality of word lines is read then stored in the page buffer; and
a memory controller configured to request the nonvolatile semiconductor memory to perform the second read operation when data at a target physical address can be read by a single second read operation.

16. The memory system according to claim 15, wherein the memory controller is further configured to request the nonvolatile semiconductor memory to perform the first read operation when data at the target physical address cannot be read by a single second read operation.

17. The memory system according to claim 16, wherein the memory controller is configured to receive a plurality of read requests in sequence and determine whether the data at target addresses of the read requests received in sequence are stored in memory cells connected to a same word line among the plurality of word lines, and if so, request the nonvolatile to perform the first read operation to read the data at the target addresses of the read requests received in sequence.

18. The memory system according to claim 16, wherein
the nonvolatile semiconductor memory includes a plurality of planes, and
the memory controller is further configured to cause the nonvolatile semiconductor memory to perform a third read operation for reading data in parallel from corresponding word lines in the plurality of planes.
